(19) United States
(12) Patent Application Publication
(10) Pub. No.: US 2011/0011458 A1
(43) Pub. Date: Jan. 20, 2011

(54) SOLAR CELL AND METHOD FOR MANUFACTURING SOLAR CELL

(75) Inventors: Atsushi DENDA, Chino (JP); Hiromi SAITO, Chino (JP)

Correspondence Address: GLOBAL IP COUNSELORS, LLP, 1233 20TH STREET, NW, SUITE 700, WASHINGTON, DC, 20036-2680, US

(73) Assignee: SEIKO EPSON CORPORATION, Tokyo (JP)

(21) Appl. No.: 12/830,807

(22) Filed: Jul. 6, 2010

(30) Foreign Application Priority Data
Jul. 14, 2009 (JP) 2009-165345

(51) Int. Cl. H01L 31/0256; H01L 31/18

(52) U.S. Cl. 136/261; 438/80; 257/E31.032; 257/E31.113

(57) ABSTRACT

A method is for manufacturing a solar cell having a plurality of unit cells connected in series, each of the unit cells including a substrate, a first electrode layer formed on the substrate, a semiconductor layer formed on the first electrode layer, and a second electrode layer formed on the semiconductor layer. The method includes forming a fluid-repellent partition portion on the substrate to partition a plurality of regions respectively corresponding to the first electrode layers of the unit cells, and applying a liquid material including a first electrode material for forming the first electrode layers on the regions of the substrate that are partitioned by the partition portion, and baking the applied liquid material to form the first electrode layers.

### CROSS-REFERENCE TO RELATED APPLICATIONS

This application claims priority to Japanese Patent Application No. 2009-165345 filed on Jul. 14, 2009. The entire disclosure of Japanese Patent Application No. 2009-165345 is hereby incorporated herein by reference.

### BACKGROUND

1. Technical Field

The present invention relates to a solar cell and to a method for manufacturing a solar cell.

2. Related Art

A solar cell converts light energy into electrical energy, and various types of configurations of solar cells have been proposed according to the semiconductor used. In recent years, CIGS-type solar cells have been emphasized for the simple manufacturing process thereof and the ability to realize high conversion efficiency. A CIGS solar cell is configured from a plurality of unit cells connected in a series, where one cell is composed, for example, of a first electrode film formed on a substrate, a thin film that includes a compound semiconductor (copper-indium-gallium-selenide) formed on the first electrode film, and a second electrode film that is formed on the thin film. The first electrode film is divided in each cell by forming a groove in a portion of the first electrode film, and the first electrode film is formed so as to straddle the space between adjacent cells. The thin film and the second electrode film are divided in each cell by forming a groove in the thin film and a portion of the second electrode film so as to extend to the first electrode film. The first electrode film and the second electrode film are electrically connected by providing a groove in a portion of the thin film so as to extend to the first electrode film, and forming the second electrode film within the groove. The second electrode film of each cell is thereby connected to the first electrode film of the adjacent cell, and the unit cells are connected in series (see Japanese Laid-Open Patent Publication No. 2002-319686, for example).

### SUMMARY

The grooves for dividing the solar cell described above into cells are formed by scribing the first electrode film or portions of the second electrode film and thin film using laser light irradiation, a metal needle, or the like. The greatest possible care must be taken during formation of the grooves so as not to cause defects in the quality of other members. A margin for machining error must therefore be added to the scribe region in which the grooves are formed, and the need arises to reserve an even wider area. However, reserving such a wide area increases the size of non-generating regions that do not contribute to the function of the solar cell, and conversion efficiency is reduced.

The present invention was developed in order to overcome at least some of the problems described above, and the present invention can be implemented in the form of the embodiments or applications described below.

A method according to a first aspect is for manufacturing a solar cell having a plurality of unit cells connected in series, each of the unit cells including a substrate, a first electrode layer formed on the substrate, a semiconductor layer formed on the first electrode layer, and a second electrode layer formed on the semiconductor layer. The method for manufacturing a solar cell includes: forming a fluid-repellent partition portion on the substrate to partition a plurality of regions respectively corresponding to the first electrode layers of the unit cells; and applying a liquid material including a first electrode material for forming the first electrode layers on the regions of the substrate that are partitioned by the partition portion, and baking the applied liquid material to form the first electrode layers.

According to this configuration, a partition portion is formed on the substrate so that the first electrode layer is partitioned for each cell, and a liquid material including a first electrode material for forming the first electrode layer is applied on the region partitioned by the partition portion. Since the partition portion is fluid repellent, the liquid material is repelled at the boundary with the partition portion and retained within the region partitioned by the partition portion. The first electrode layer is formed by baking the applied liquid material. The first electrode layer is thereby formed in unit cells. Consequently, the first electrode layer is divided into unit cell, and there is therefore no need for a conventional scribing process using laser light irradiation, a metal needle, or the like. Damage and other adverse effects on other members are therefore prevented, scribing residue can be prevented from being formed, and a highly reliable solar cell can be provided. Since there is also no longer any need to set a scribing width or the like to allow for dimensional error in scribing, a larger electrical generation region can be formed, and conversion efficiency can be enhanced.

A method according to a second aspect is for manufacturing a solar cell having a plurality of unit cells connected in series, each of the unit cells including a substrate, a first electrode layer formed on the substrate, a semiconductor layer formed on the first electrode layer, and a second electrode layer formed on the semiconductor layer. The method for manufacturing a solar cell includes: forming a fluid-repellent partition portion on the first electrode layers to partition a plurality of regions respectively corresponding to the semiconductor layers of the unit cells; and applying a liquid material including a semiconductor material for forming the semiconductor layers on the regions of the first electrode layers that are partitioned by the partition portion, and baking the applied liquid material to form the semiconductor layers.

According to this configuration, a partition portion is formed on the first electrode layer so that the semiconductor layer is partitioned for each cell, and a liquid material including a semiconductor material for forming the semiconductor layer is applied on the region partitioned by the partition portion. Since the partition portion is fluid repellent, the liquid material is repelled at the boundary with the partition portion and retained within the region partitioned by the partition portion. The semiconductor layer is formed by baking the applied liquid material. The semiconductor layer is thereby formed in unit cells. Consequently, the semiconductor layer is divided into unit cells, and there is therefore no need for a conventional scribing process using laser light irradiation, a metal needle, or the like. Damage and other adverse effects on other members are therefore prevented, scribing residue can be prevented from being formed, and a highly reliable solar cell can be provided. Since there is also no longer any need to set a scribing width or the like to accommodate dimensional error in scribing, a larger electrical generation region can be formed, and conversion efficiency can be enhanced.

A method according to a third aspect is for manufacturing a solar cell having a plurality of unit cells connected in series, each of the unit cells including a substrate, a first electrode layer formed on the substrate, a semiconductor layer formed on the first electrode layer, and a second electrode layer formed on the semiconductor layer. The method for manufacturing a solar cell includes: forming a fluid-repellent partition portion on the first electrode layer to partition a plurality of regions respectively corresponding to the second electrode layers of the unit cells; and applying a liquid material including a second electrode material for forming the second electrode layers on the regions of the semiconductor layers that are partitioned by the partition portion, and baking the applied liquid material to form the second electrode layers.

According to this configuration, a partition portion is formed on the substrate so that the second electrode layer is partitioned for each cell, and a liquid material including a second electrode material for forming the second electrode layer is applied on the region partitioned by the partition portion. Since the partition portion is fluid repellent, the liquid material is repelled at the boundary with the partition portion and retained within the region partitioned by the partition portion. The second electrode layer is formed by baking the applied liquid material. The semiconductor layer is thereby formed in unit cells. Consequently, the second electrode layer is divided into unit cells, and there is therefore no need for a conventional scribing process using laser light irradiation, a metal needle, or the like. Damage and other adverse effects on other members are therefore prevented, scribing residue can be prevented from being formed, and a highly reliable solar cell can be provided. Since there is also no longer any need to set a scribing width or the like to accommodate dimensional error in scribing, a larger electrical generation region can be formed, and conversion efficiency can be enhanced.

A method according to a fourth aspect is for manufacturing a solar cell having a plurality of unit cells connected in series, each of the unit cells including a substrate, a first electrode layer formed on the substrate, a semiconductor layer formed on the first electrode layer, and a second electrode layer formed on the semiconductor layer. The method for manufacturing a solar cell includes: forming a fluid-repellent first partition portion on the substrate to partition a plurality of regions respectively corresponding to the first electrode layers of the unit cells; applying a liquid material including a first electrode material for forming the first electrode layers on the regions of the substrate that are partitioned by the first partition portion, and baking the applied liquid material to form the first electrode layers; forming a fluid-repellent second partition portion on the first electrode layer to partition a plurality of regions respectively corresponding to the semiconductor layers of the unit cells; applying a liquid material including a semiconductor material for forming the semiconductor layers on the regions of the first electrode layers that are partitioned by the second partition portion, and baking the applied liquid material to form the semiconductor layers; forming a fluid-repellent third partition portion on the first electrode layer to partition a plurality of regions respectively corresponding to the second electrode layers of the unit cells; and applying a liquid material including a second electrode material for forming the second electrode layers on the regions of the semiconductor layers that are partitioned by the third partition portion, and baking the applied liquid material to form the second electrode layers.

According to this configuration, a partition portion is formed on the substrate so that the first electrode layer is partitioned for each cell, and a liquid material including a first electrode material for forming the first electrode layer is applied on the region partitioned by the partition portion. Since the partition portion is fluid repellent, the liquid material is repelled at the boundary with the partition portion and retained within the region partitioned by the partition portion. The first electrode layer is formed by baking the applied liquid material. The first electrode layer is thereby formed in unit cells. In the same manner, the semiconductor layer is formed in unit cells by the partition portion for partitioning the semiconductor layer. The second electrode layer is also formed in unit cells by the partition portion for partitioning the second electrode layer. Consequently, there is no need for a conventional scribing process using laser light irradiation, a metal needle, or the like. Damage and other adverse effects on other members are therefore prevented, scribing residue can be prevented from being formed, and a highly reliable solar cell can be provided. Since there is also no longer any need to set a scribing width or the like to accommodate dimensional error in scribing, a larger electrical generation region can be formed, and conversion efficiency can be enhanced.

In the method for manufacturing a solar cell as described above, the forming of the first, second or third partition portions preferably include applying a liquid material including a fluid-repellent material to form the first, second or third partition portion, and drying the applied liquid material.

According to this configuration, the partition portion is formed by applying a liquid material including a fluid-repellent material and drying the liquid material. Since a printing method, an inkjet method, or another method is thus used to form the partition portion and form the layers formed in the region partitioned by the partition portion, the number of manufacturing steps can be reduced, and productivity can be enhanced.

In the method for manufacturing a solar cell as described above, the forming of the first, second and third partition portions preferably includes inactivating the fluid-repellent properties of the first, second or third partition portion by a heat treatment performed at a predetermined temperature.

According to this configuration, since the fluid-repellent properties of the partition portion are inactivated at a predetermined temperature, adhesion between each layer can be maintained by forming the other layers after the fluid-repellent properties have been inactivated.

In the method for manufacturing a solar cell as described above, the forming of the first, second and third partition portions preferably includes applying a liquid material including a fluid-repellent material having a fluoroalkyl silane as a primary component to form the first, second or third partition portion.

According to this configuration, the layers can be divided for each cell by a fluid-repellent fluoroalkyl silane.

A solar cell having a plurality of unit cells connected in series according to a fifth aspect includes a substrate, a first electrode layer formed on the substrate, a semiconductor layer formed on the first electrode layer, and a second electrode layer formed on the semiconductor layer, the second electrode being also formed on an end surface of the semiconductor layer extending to the first electrode layer.

According to this configuration, the second electrode layer is formed on the semiconductor layer so as to be on an end surface of the semiconductor layer. Specifically, the second electrode layer is formed in the outermost peripheral portion of each cell. Consequently, the region in which the first electrode layer, the semiconductor layer, and the second electrode layer overlap, i.e., the region that contributes to electrical generation, can be increased in size, and conversion efficiency can be increased.

In the solar cell as described above, the second electrode layer formed on the end surface of the semiconductor layer in one of the unit cells is preferably spaced apart from an adjacent one of the unit cells.

According to this configuration, the second electrode layer is formed in the outermost peripheral portion of each cell, and a space is formed between the second electrode layer and the adjacent other cells. Specifically, non-generating regions that do not contribute to electrical generation are eliminated from each cell. Consequently, non-generating regions that occupy space in the solar cell without contributing to electrical generation are eliminated, the size of the electrical generation region that contributes to electrical generation can be increased, and conversion efficiency can be enhanced.

### BRIEF DESCRIPTION OF THE DRAWINGS

Referring now to the attached drawings which form a part of this original disclosure:

FIG. 1 is a view showing the structure of the solar cell;

FIG. 2 is a process view showing the method for manufacturing a solar cell; and

FIG. 3 is a process view showing the method for manufacturing a solar cell.

### DETAILED DESCRIPTION OF EXEMPLARY EMBODIMENTS

An embodiment of the present invention will be described hereinafter with reference to the drawings. Each of the members shown in the drawings is shown sufficiently large to recognize, and members are not shown to scale in relation to each other.

Structure of Solar Cell

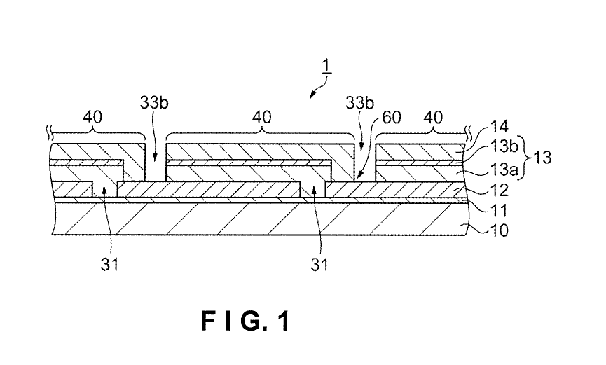

The structure of the solar cell will first be described. In the present embodiment, the structure of a CIGS-type solar cell will be described. FIG. 1 is a sectional view showing the structure of the solar cell according to the present embodiment.

As shown in FIG. 1, the solar cell 1 is has an aggregate of unit cells 40 that are composed of a substrate 10; a base layer 11 formed on the substrate 10; a first electrode layer 12 formed on the base layer 11; a semiconductor layer 13 formed on the first electrode layer 12; and an second electrode layer 14 formed on the semiconductor layer 13.

The first electrode layer 12 is divided for each cell by first groove portions 31, and the first electrode layer 12 is formed so as to bridge the spaces between adjacent unit cells 40. The second electrode layer 14 and the semiconductor layer 13 formed on the first electrode layer 12 are divided for each cell by spaces 33b. The second electrode layer 14 is formed on the semiconductor layer 13 and on end surfaces of the semiconductor layer 13 that extend to the first electrode layer 12. The second electrode layer 14 of each unit cell 40 and the first electrode layer 12 of the other adjacent unit cells 40 are thereby electrically connected, and the unit cells 40 are connected in series. The desired voltage in the solar cell 1 can thus be designed and changed to any value by appropriately setting the number of unit cells 40 that are connected in series.

The substrate 10 is a substrate in which at least the surface thereof on the side of the first electrode layer 12 has insulating properties. Specific examples of substrates that can be used include glass (blue sheet glass or the like) substrates, stainless steel substrates, polyimide substrates, and carbon substrates.

The base layer 11 is a layer having insulating properties that is formed on the substrate 10, and an insulation layer primarily composed of SiO₂ (silicon dioxide), or an iron fluoride layer may be provided. The base layer 11 has insulation properties, and has the function of maintaining adhesion between the substrate 10 and the first electrode layer 12 formed on the substrate 10. The base layer 11 may be omitted when the substrate 10 has the characteristics described above.

The first electrode layer 12 is formed on the base layer 11. The first electrode layer 12 is electrically conductive, and may be formed using molybdenum (Mo), for example.

The semiconductor layer 13 is composed of a first semiconductor layer 13a and a second semiconductor layer 13b. The first semiconductor layer 13a is formed on the first electrode layer 12, and is a p-type semiconductor layer that includes copper (Cu), indium (In), gallium (Ga, and selenium (Se) (CIGS semiconductor layer).

The second semiconductor layer 13b is formed on the first semiconductor layer 13a, and is a cadmium sulfide (CdS), zinc oxide (ZnO), indium sulfide (InS), or other n-type semiconductor layer.

The second electrode layer 14 is a transparent electrode layer, and is composed of ZnOAl or another transparent electrode (TCO: transparent conducting oxides), AZO, or the like. The second electrode layer 14 is formed on the second semiconductor layer 13b and on the end surfaces of the semiconductor layer 13, and the first electrode layer 12 and the second electrode layer 14 are electrically connected at a connection part 60. By thus forming the second electrode layer 14 on the end surfaces of the semiconductor layer 13, and providing the spaces 33b between the adjacent unit cells 40, i.e., by providing the second electrode layer 14 in the outermost peripheral portions of the unit cells 40, the region in which the first electrode layer 12, the semiconductor layer 13, and the second electrode layer 14 overlap, i.e., the region that contributes to electrical generation, can be made larger.

When sunlight or other light is incident on the CIGS-type solar cell 1 configured as described above, electrons (−) and positive holes (+) occur in pairs in the semiconductor layer 13, and the electrons (−) collect in the n-type semiconductor layer, and the positive holes (+) collect in the p-type semiconductor layer at the joint surface between the p-type semiconductor layer (first semiconductor layer 13a) and the n-type semiconductor layer (second semiconductor layer 13b). As a result, an electromotive force occurs between the n-type semiconductor layer and the p-type semiconductor layer. In this state, a current can be directed to the outside by connecting an external conductor to the first electrode layer 12 and the second electrode layer 14.

Method for Manufacturing Solar Cell

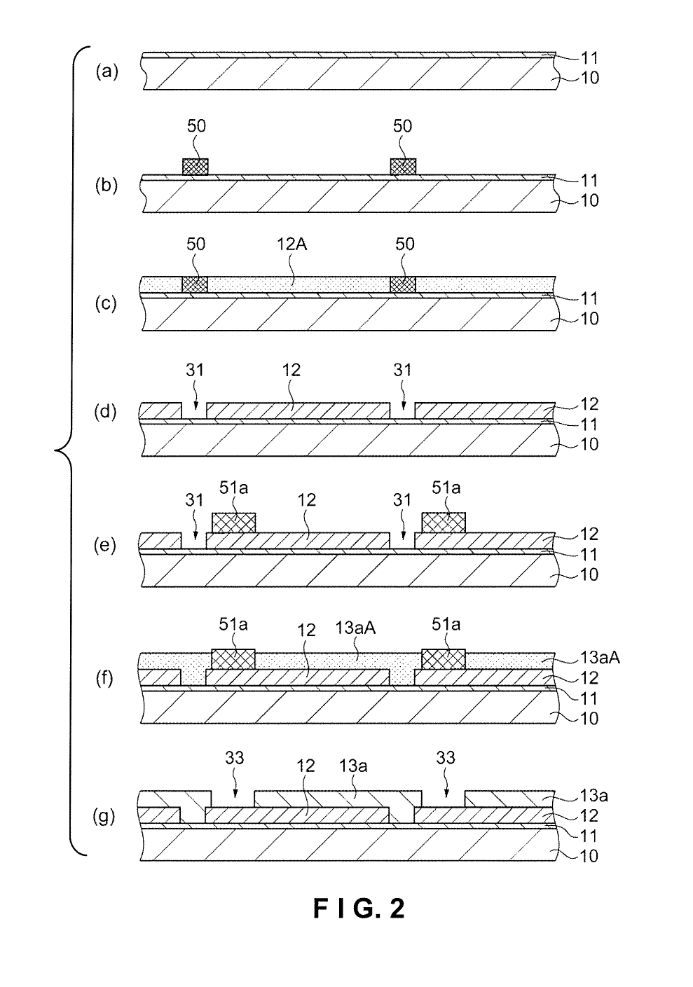

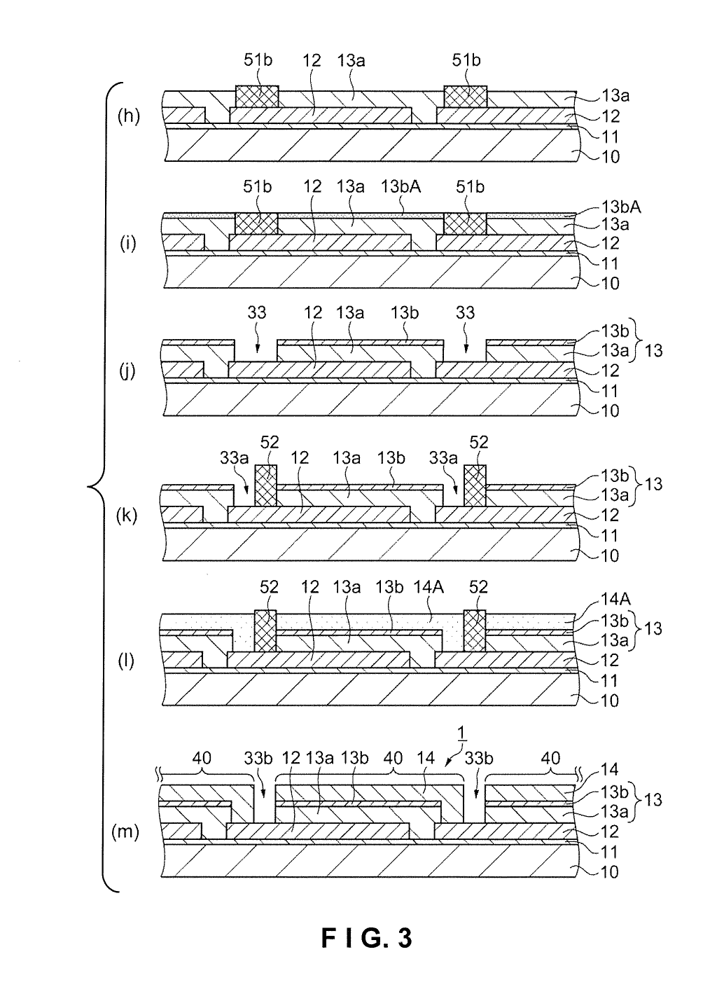

The method for manufacturing the solar cell will next be described. In the present embodiment, a method for manufacturing a CIGS-type solar cell will be described. FIGS. 2 and 3 are process views showing the method for manufacturing a solar cell according to the present embodiment.

In a base layer formation step shown in FIG. 2(a), an insulation layer primarily composed of SiO₂ (silicon dioxide) or an iron fluoride base layer 11 is formed on one surface of a substrate 10 composed of blue sheet glass, stainless steel, or other material. The base layer 11 can be formed by heat treatment or another method. The base layer formation step may be omitted when the substrate 10 as such has the effects of the base layer described above.

In a first partition portion formation step shown in FIG. 2(b), fluid-repellent partition portions 50 are formed on the base layer 11 to partition the region in which the first electrode layer 12 is formed for each unit cell 40. Specifically, the fluid-repellent partition portions 50 (first partition portion) are formed by applying a liquid material that includes a fluid-repellent material for forming the partition portions 50 on the base layer 11 using a printing method, an inkjet method, or another method, and baking the applied liquid material. A material composed primarily of a fluoroalkyl silane may be used as the fluid-repellent material.

In a first electrode layer formation step shown in FIGS. 2(c) and 2(d), a liquid material 12A that includes a first electrode material for forming the first electrode layer 12 is applied on the base layer 11 in the region partitioned by the partition portions 50. Specifically, a liquid material 12A that includes molybdenum (Mo) for forming the first electrode layer 12 is applied on the region partitioned by the partition portions 50 using a printing method, an inkjet method, or another method. The liquid material 12A applied on the base layer 11 spreads into the region partitioned by the partition portions 50, but because the partition portions 50 are fluid-repellent, the partition portions 50 repel the liquid material 12A and ensure that the liquid material 12A stays in the application region. As shown in FIG. 2(d), the first electrode layer 12 is formed by baking the applied liquid material 12A using a heat treatment at a predetermined temperature. In the process of baking the liquid material 12A, the fluid-repellent properties of the partition portions 50 are inactivated, the form of the partition portions 50 is lost, and first groove portions 31 are formed in the regions in which the partition portions 50 were formed.

The second partition portion formation step will next be described. The second partition portion formation step is a step for partitioning for each unit cell 40 the region in which the semiconductor layer 13 (first semiconductor layer 13a, second semiconductor layer 13b) is formed, and is performed by a second first-partition portion formation step and a second second-partition formation step. In the second first-partition portion formation step shown in FIG. 2(e), fluid-repellent partition portions 51a (second partition portion) are formed for partitioning for each unit cell 40 the region on the first electrode layer 12 in which the first semiconductor layer 13a is formed. Specifically, the fluid-repellent partition portions 51a are formed by using a printing method, an inkjet method, or another method to apply a liquid material that includes a fluid-repellent material for forming the partition portions 51a on the first electrode layer 12, and drying the applied liquid material. A material composed primarily of a fluoroalkyl silane may be used as the fluid-repellent material.

The semiconductor layer formation step will next be described. In the first semiconductor layer formation step shown in FIGS. 2(f) and 2(g), a liquid material 13aA that includes a first semiconductor material for forming the first semiconductor layer 13a is applied on the first electrode layer 12 in the region partitioned by the partition portions 51a. Specifically, a liquid material 13aA that includes a compound semiconductor material having copper (Cu), indium (In), gallium (Ga), and selenium (Se) for forming the first semiconductor layer 13a is applied on the region partitioned by the partition portions 51a by a printing method, an inkjet method, or another method. The applied liquid material 13aA spreads into the region partitioned by the partition portions 51a, but because the partition portions 51a are fluid-repellent, the partition portions 51a repel the liquid material 13aA and ensure that the liquid material 13aA stays in the application region. As shown in FIG. 2(g), the first semiconductor layer 13a is formed by baking the applied liquid material 13aA using a heat treatment at a predetermined temperature. A p-type semiconductor layer (CIGS layer) is thereby formed. In the process of baking the liquid material 13aA, the fluid-repellent properties of the partition portions 51a are inactivated, the form of the partition portions 51a is lost, and groove portions 33 are formed in the regions in which the partition portions 51a were formed.

In the second second-partition portion formation step shown in FIG. 3(h), fluid-repellent partition portions 51b for partitioning for each unit cell 40 the region on the first electrode layer 12 in which the second semiconductor layer 13b is formed, the first electrode layer 12 having the groove portions 33. Specifically, the fluid-repellent partition portions 51b are formed by using a printing method, an inkjet method, or another method to apply a liquid material that includes a fluid-repellent material for forming the partition portions 51b on the first electrode layer 12, and drying the applied liquid material. A material composed primarily of a fluoroalkyl silane may be used as the fluid-repellent material.

In a second semiconductor layer formation step shown in FIGS. 3(i) and 3(j), a liquid material 13bA that includes a second semiconductor material for forming the second semiconductor layer 13b is applied on the region of the first semiconductor layer 13a partitioned by the partition portions 51b. Specifically, the liquid material 13bA that includes a second semiconductor material having CdS, ZnO, InS, or another compound for forming the second semiconductor layer 13b is applied on the region partitioned by the partition portions 51b using a printing method, an inkjet method, or another method. The applied liquid material 13bA spreads into the region partitioned by the partition portions 51b, but because the partition portions 51b are fluid-repellent, the partition portions 51b repel the liquid material 13bA and ensure that the liquid material 13bA stays in the application region. As shown in FIG. 3(j), the second semiconductor layer 13b is formed by baking the applied liquid material 13bA using a heat treatment at a predetermined temperature. An n-type semiconductor layer is thereby formed. A semiconductor layer 13 having a first semiconductor layer 13a and a second semiconductor layer 13b is thus formed. In the process of baking the liquid material 13bA, the fluid-repellent properties of the partition portions 51b are inactivated, the form of the partition portions 51b is lost, and groove portions 33 are formed in the regions in which the partition portions 51b were formed.

In a third partition portion formation step shown in FIG. 3(k), fluid-repellent partition portions 52 are formed for partitioning for each unit cell 40 the region on the first electrode layer 12 in which the second electrode layer 14 is formed. Specifically, the fluid-repellent partition portions 52 (third partition portion) are formed by using a printing method, an inkjet method, or another method to apply a liquid material that includes a fluid-repellent material for forming the partition portions 52 on the first electrode layer 12, and drying the applied liquid material. A material composed primarily of a fluoroalkyl silane may be used as the fluid-repellent material. In the third partition portion formation step, the partition portions 52 are formed so that spaces 33a are formed between the semiconductor layer 13 and the partition portions 52. The second electrode layer 14 is formed in the spaces 33a in the subsequent step.

In a second electrode layer formation step shown in FIGS. 3(l) and 3(m), a liquid material 14A that includes a second electrode material for forming the second electrode layer 14 is applied on the semiconductor layer 13 and in the spaces 33a, in the region partitioned by the partition portions 52. Specifically, a liquid material 14A that includes ZnOAl or another transparent electrode (TCO) material for forming the second electrode layer 14 is applied on the region partitioned by the partition portions 52 using a printing method, an inkjet method, or another method. The liquid material 14A applied on the semiconductor layer 13 and in the spaces 33a spreads into the region partitioned by the partition portions 52, but because the partition portions 52 are fluid-repellent, the partition portions 52 repel the liquid material 14A and ensure that the liquid material 14A stays in the application region. As shown in FIG. 3(m), the second electrode layer 14 is formed by baking the applied liquid material 14A using a heat treatment at a predetermined temperature. The first electrode layer 12 and the second electrode layer 14 are thereby electrically connected. In the process of baking the liquid material 14A, the fluid-repellent properties of the partition portions 52 are inactivated, the form of the partition portions 52 is lost, and spaces 33b are formed in the regions in which the partition portions 52 were formed.

By the process described above, a CIGS-type solar cell 1 is manufactured in which a plurality of unit cells 40 is connected in series.

The effects described below are obtained through the embodiment described above.

(1) The partition portions 50 are foamed to divide the first electrode layer 12 for each unit cell 40. The partition portions 51a, 51b are formed to divide the semiconductor layer 13 (13a, 13b) for each unit cell 40. The partition portions 52 are then formed to divide the second electrode layer 14 for each unit cell 40. There is thus no need to use laser light irradiation, a metal needle, or another method (a scribing process) to form divisions into unit cells 40 in the present embodiment. Consequently, there is no scribing residue generated, and no damage to other members. A highly reliable solar cell can thereby be provided. Since there is also no need to set a scribing width or the like to allow for error in the scribing process, a larger electrical generation region can be formed, and conversion efficiency can be enhanced.

(2) Spaces 33a are formed in the semiconductor layer 13, and partition portions 52 are formed. The second electrode layer 14 is formed in the spaces 33a. Since the second electrode layer 14 is thereby formed in the outermost peripheral portion of each unit cell 40, it is possible to increase the size of the region in which the first electrode layer 12, the semiconductor layer 13, and the second electrode layer 14 overlap, i.e., the region that contributes to electrical generation.

The present invention is not limited to the embodiments described above, and may include such modifications as those described below.

Modification 1

In the embodiment described above, the liquid material 12A including a first electrode material for forming the first electrode layer 12, as well as the other liquid materials, are applied using a printing method, an inkjet method, or another method, but this configuration is not limiting. For example, the liquid material 12A may be applied to the substrate 10 by a dipping method. Even when such a method is employed, because the partition portions 50 are fluid-repellent, the partition portions 50 repel the liquid material 12A, and the liquid material 12A can be applied in a predetermined region. A dipping method may be used to apply the other liquid materials 13aA, 13bA, and 14A as well.

Modification 2

First through third partition portion formation steps are described in the embodiment above, but a configuration may also be adopted in which at least one partition portion formation step is performed, and the other partition portion formation steps are omitted. The scribing process can be eliminated in this configuration as well, and damage to other members can be reduced.

Modification 3

In the embodiment described above, a description is provided of the structure and other aspects of a CIGS-type solar cell 1, for receiving light from the side of the second electrode layer 14, but the solar cell 1, may also be a CIGS-type solar cell 1 that is capable of receiving light from the side of the substrate 10 as well as from the side of the second electrode layer 14. In this case, a transparent substrate is used as the substrate 10. For example, a glass substrate, a PET substrate, an organic transparent substrate, or the like may be used. Using a transparent substrate enables light to be received from the surface of the substrate 10. The first electrode layer 12 is a transparent electrode layer, and is a ZnOAl or other transparent electrode (TCO: transparent conducting oxides) layer, for example. By forming a transparent electrode layer, light that is incident from the side of the substrate 10 can be made to pass through to the semiconductor layer 13. The same effects as those described above can be obtained through this configuration as well.

### GENERAL INTERPRETATION OF TERMS

In understanding the scope of the present invention, the term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives. Also, the terms “part,” “section,” “portion,” “member” or “element” when used in the singular can have the dual meaning of a single part or a plurality of parts. Finally, terms of degree such as “substantially”, “about” and “approximately” as used herein mean a reasonable amount of deviation of the modified term such that the end result is not significantly changed. For example, these terms can be construed as including a deviation of at least ±5% of the modified term if this deviation would not negate the meaning of the word it modifies.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents.

What is claimed is:

1. A method for manufacturing a solar cell having a plurality of unit cells connected in series, each of the unit cells including a substrate, a first electrode layer formed on the substrate, a semiconductor layer formed on the first electrode layer, and a second electrode layer formed on the semiconductor layer, the method for manufacturing a solar cell comprising:
forming a fluid-repellent first partition portion on the substrate to partition a plurality of regions respectively corresponding to the first electrode layers of the unit cells; and
applying a liquid material including a first electrode material for forming the first electrode layers on the regions of the substrate that are partitioned by the first partition portion, and baking the applied liquid material to form the first electrode layers.

2. A method for manufacturing a solar cell having a plurality of unit cells connected in series, each of the unit cells including a substrate, a first electrode layer formed on the substrate, a semiconductor layer formed on the first electrode layer, and a second electrode layer formed on the semiconductor layer, the method for manufacturing a solar cell comprising:
forming a fluid-repellent partition portion on the first electrode layers to partition a plurality of regions respectively corresponding to the semiconductor layers of the unit cells; and
applying a liquid material including a semiconductor material for forming the semiconductor layers on the regions of the first electrode layers that are partitioned by the partition portion, and baking the applied liquid material to form the semiconductor layers.

3. A method for manufacturing a solar cell having a plurality of unit cells connected in series, each of the unit cells including a substrate, a first electrode layer formed on the substrate, a semiconductor layer formed on the first electrode layer, and a second electrode layer formed on the semiconductor layer, the method for manufacturing a solar cell comprising:
forming a fluid-repellent partition portion on the first electrode layer to partition a plurality of regions respectively corresponding to the second electrode layers of the unit cells; and
applying a liquid material including a second electrode material for forming the second electrode layers on the regions of the semiconductor layers that are partitioned by the partition portion, and baking the applied liquid material to form the second electrode layers.

4. The method for manufacturing a solar cell according to claim 1, further comprising
forming a fluid-repellent second partition portion on the first electrode layer to partition a plurality of regions respectively corresponding to the semiconductor layers of the unit cells;
applying a liquid material including a semiconductor material for forming the semiconductor layers on the regions of the first electrode layers that are partitioned by the second partition portion, and baking the applied liquid material to form the semiconductor layers;
forming a fluid-repellent third partition portion on the first electrode layer to partition a plurality of regions respectively corresponding to the second electrode layers of the unit cells; and
applying a liquid material including a second electrode material for forming the second electrode layers on the regions of the semiconductor layers that are partitioned by the third partition portion, and baking the applied liquid material to form the second electrode layers.

5. The method for manufacturing a solar cell according to claim 4, wherein
the forming of the first, second or third partition portions includes applying a liquid material including a fluid-repellent material to form the first, second or third partition portion, and drying the applied liquid material.

6. The method for manufacturing a solar cell according to claim 4, wherein
the forming of the first, second and third partition portions includes inactivating the fluid-repellent properties of the first, second or third partition portion by a heat treatment performed at a predetermined temperature.

7. The method for manufacturing a solar cell according to claim 4, wherein
the forming of the first, second and third partition portions includes applying a liquid material including a fluid-repellent material having a fluoroalkyl silane as a primary component to form the first, second or third partition portion.

8. A solar cell having a plurality of unit cells connected in series, the solar cell comprising:
a substrate;
a first electrode layer formed on the substrate;
a semiconductor layer formed on the first electrode layer; and
a second electrode layer formed on the semiconductor layer, the second electrode being also formed on an end surface of the semiconductor layer extending to the first electrode layer.

9. The solar cell according to claim 8, wherein
the second electrode layer formed on the end surface of the semiconductor layer in one of the unit cells is spaced apart from an adjacent one of the unit cells.
